(19) United States
(12) Patent Application Publication
(10) Pub. No.: US 2026/0198259 A1
(43) Pub. Date: Jul. 9, 2026

(54) TRANSPORTING APPARATUS AND TRANSPORTING SYSTEM INCLUDING THE SAME

(71) Applicant: Samsung Electronics Co., Ltd., Suwon-si (KR)

(72) Inventors: So Young BAEK, Suwon-si (KR); Seung Gyu KANG, Suwon-si (KR); Kyu Sang KO, Suwon-si (KR); Sang Min KIM, Suwon-si (KR); Young Wook KIM, Suwon-si (KR); Hyoeng Rak KIM, Suwon-si (KR); Jeong Hun LIM, Suwon-si (KR); Min-Gu CHANG, Suwon-si (KR); Jun Hyuk CHANG, Suwon-si (KR)

(21) Appl. No.: 19/404,157

(22) Filed: Dec. 1, 2025

(30) Foreign Application Priority Data
Jan. 6, 2025 (KR) 10-2025-0001487

(51) Int. Cl. H10P 72/30; H10P 72/76

(52) U.S. Cl. CPC H10P 72/3202; H10P 72/3218; H10P 72/7602

(57) ABSTRACT

A transporting apparatus transports a pod that houses one or more semiconductor wafers, and the transporting apparatus includes a rail including a straight section and a curved section that form a transport path for the pod, a driving unit that provides power to move the pod along the rail, a cam guide positioned between the rail and the driving unit and connected to the driving unit, a first roller follower positioned within a hole of the cam guide, and a second roller follower positioned within a hole of the rail. The driving unit moves the cam guide, the first roller follower moves within the hole of the cam guide, and the second roller follower moves relative to the rail.

### CROSS-REFERENCE TO RELATED APPLICATION

This application claims priority from Korean Patent Application No. 10-2025-0001487 filed on Jan. 6, 2025 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a transporting apparatus capable of changing directions in two or more axes and a transporting system including the transporting apparatus.

### 2. Description of the Related Art

In the manufacturing process of semiconductor devices, objects being transported, such as semiconductor wafers, may be stored in storage and retention devices. For example, containers such as front opening unified pods (FOUPs) for housing wafers may be accommodated in storage and retention devices equipped with multiple shelves.

However, to facilitate the smooth transportation of objects from the storage and retention devices within a limited space, it is beneficial to provide a transporting apparatus with a reduced spatial footprint.

### SUMMARY

An objective of the present disclosure is to provide a transporting apparatus with enhanced usability.

Another objective of the present disclosure is to provide a transporting system with enhanced usability.

The objectives of the present disclosure are not limited to those mentioned above, and other objectives not explicitly stated will be clearly understood by those skilled in the art based on the following description.

According to some embodiments, a transporting apparatus for transporting a pod that is configured to house one or more semiconductor wafers is provided. The transporting apparatus comprises a rail including a straight section and a curved section that form a transport path for the pod, a driving unit configured to provide power to move the pod along the rail, a cam guide positioned between the rail and the driving unit and connected to the driving unit, a first roller follower positioned within a hole of the cam guide, and a second roller follower positioned within a hole of the rail, wherein the driving unit is configured to move the cam guide, the first roller follower is configured to move within the hole of the cam guide, and the second roller follower is configured to move relative to the rail.

According to some embodiments, a transporting apparatus for transporting a pod that is configured to house one or more semiconductor wafers is provided. The transporting apparatus comprises a rail including a first rail section, along which the pod is movable in a first direction, and a second rail section, along which the pod is movable in a second direction different from the first direction, a driving unit configured to provide power to move the pod along the rail, a cam guide positioned between the rail and the driving unit in a vertical direction and connected to the driving unit, a first roller follower connected to the cam guide, a second roller follower connected to the rail, and a shaft extending vertically through the cam guide and the rail, the shaft connecting the first roller follower and the second roller follower, wherein the driving unit is configured to move the cam guide, the first roller follower is configured to move relative to the cam guide, the second roller follower is configured to move relative to the rail, and the first and second roller followers move in the first and second directions.

According to some embodiments, a transporting system comprises first and second locations where pods that are configured to house one or more semiconductor wafers are stored, and a transporting robot movable in a horizontal direction and a vertical direction, wherein the transporting robot includes a transporting apparatus configured to move a pod between the first and second locations, the transporting apparatus includes a rail including a curved section and a straight section connected to the curved section, a driving unit configured to provide power to move the pod along the rail, a cam guide positioned between the rail and the driving unit in the vertical direction and connected to the driving unit, a first roller follower positioned within and connected to the cam guide; a second roller follower positioned within and connected to the rail, and a shaft extending vertically through the cam guide and the rail, wherein the first and second roller followers are attached to the shaft, and the driving unit is configured to move the cam guide, the first roller follower is configured to move relative to the cam guide, and the second roller follower is configured to move relative to the rail, wherein the first and second roller followers move along the curved section and the straight section.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic perspective view of a transporting apparatus according to some embodiments;

FIG. 2 is a cross-sectional view of the transporting apparatus according to some embodiments;

FIGS. 3 through 8 are plan views illustrating the operation of the transporting apparatus according to some embodiments;

FIG. 9 is a flowchart illustrating the operation of the transporting apparatus according to some embodiments;

FIG. 10 is a diagram for explaining a transporting system including the transporting apparatus according to some embodiments.

### DETAILED DESCRIPTION

Embodiments of the present disclosure will hereinafter be described with reference to the accompanying drawings.

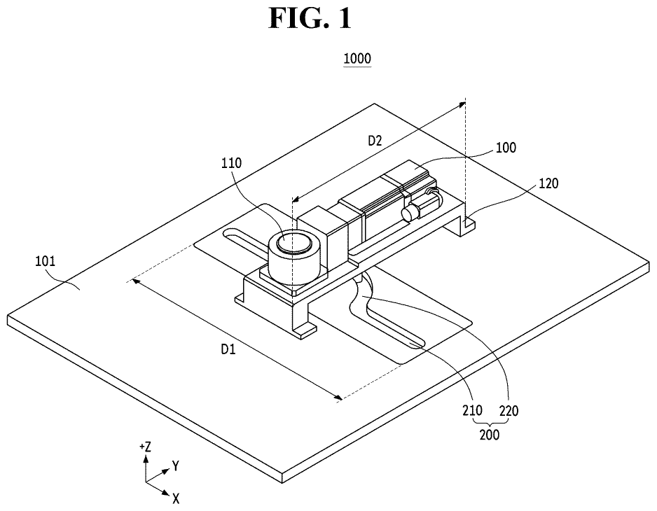

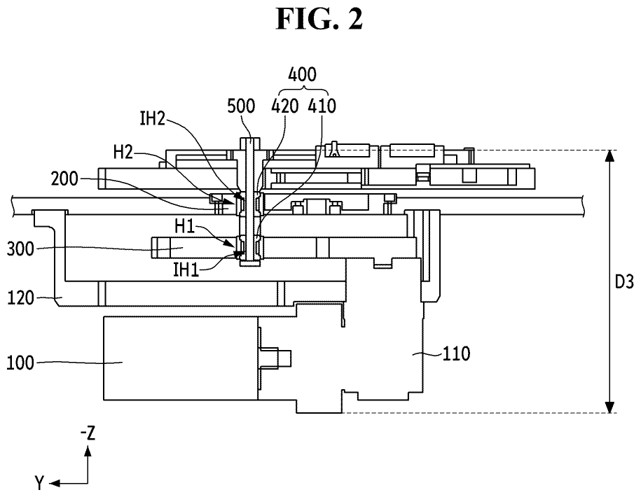

FIG. 1 is a schematic perspective view of a transporting apparatus according to some embodiments. FIG. 2 is a cross-sectional view of the transporting apparatus according to some embodiments.

Referring to FIGS. 1 and 2, a transporting apparatus 1000 may include a driving unit 100, a rail 200, a cam guide 300, a roller follower 400, and a shaft 500, and may further include a connection unit 110 and a support unit 120.

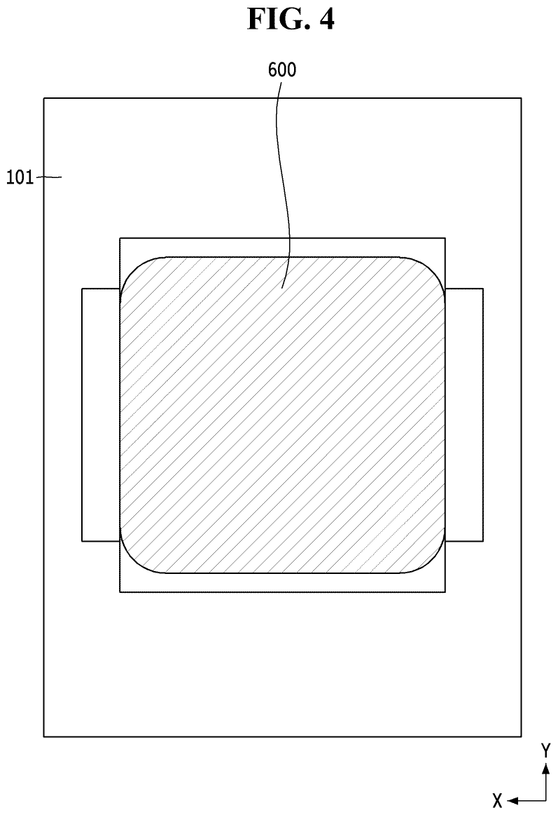

The driving unit 100 may provide power for a transported object (“600” in FIG. 4) to move along the rail 200. For example, the driving unit 100 may be a motor. The transported object may comprise a front opening unified pod (FOUP), or a pod 600, that houses one or more semiconductor wafers that may be used in a semiconductor device manufacturing processes. For example, the transport device 1000 and the FOUP can be connected or disconnected through mechanical, electronic, and/or precise position control mechanisms. Specifically, the transport device 1000 can use at least one of a mechanically attached clamping method or a vacuum suction method using a suction pad to connect or disconnect the FOUP, and can also use a combination of these methods as needed. In addition, the transport device 1000 can read information of the FOUP using an electronic identification code attached to the FOUP, and can be connected or disconnected through an electronic interface method to connect or disconnect a specific FOUP.

The rail 200 may form a transport path along which the transported pod 600 moves. The rail 200 may include an elongated opening that may extend in a non-linear direction, for example, with the rail 200 including a straight section 210 and a curved section 220. For example, the straight section 210 may extend in a first horizontal direction X, which will be described later. The curved section 220 may be continuously connected to the straight section 210. The curved section 220 may be provided in a curved shape to allow the transported pod 600 to rotate. As illustrated in FIG. 1, the curved section 220 may comprise a rounded, circular shape, with opposing ends of the curved section 220 attached to straight sections 210. By being continuously connected, the curved section 220 and the straight sections 210 may be unbroken or uninterrupted without walls or other structures separating the curved section 220 from the straight sections 210.

The shape of the rail 200 is not limited to that illustrated in FIGS. 1 and 2. For example, the lengths of the straight section 210 and the curved section 220 and the numbers of straight sections 210 and curved sections 220 are not particularly limited and may vary.

In some embodiments, the first horizontal direction X may refer to the direction in which the straight section 210 extends. A second horizontal direction Y may refer to the direction perpendicular to the first horizontal direction X. A first vertical direction +Z may refer to the height direction perpendicular to both the first and second horizontal directions X and Y. A second vertical direction −Z may refer to the direction parallel to, but opposite to, the first vertical direction +Z. In some embodiments, the second vertical direction −Z may refer to the direction toward the ceiling where the transporting apparatus 1000 is installed. In some embodiments, the straight sections 210 on opposing sides of the curved section 220 may be parallel to one another, and in the example of FIG. 1, the straight sections 210 may be co-linear with one another and may lie within the same axis or line.

In some embodiments, the curved section 220 may be referred to as a first rail section, and the straight section 210 may be referred to as a second rail section. The curved section 220 may enable the transported pod 600 to perform rotational movement, and the straight section 210 may enable the transported pod 600 to perform translational movement. The curved section 220 and the straight section 210 may enable the transported pod 600 to move in different directions, for example, in the first horizontal direction X and the second horizontal direction Y.

The cam guide 300 may be positioned between the rail 200 and the driving unit 100 with respect to the first vertical direction +Z and/or the second vertical direction −Z. The cam guide 300 may be connected to the driving unit 100. The cam guide 300 may guide the movement of the transported pod 600 along the rail 200.

The roller follower 400 may include a first roller follower 410 mounted on the cam guide 300 and a second roller follower 420 mounted on the rail 200.

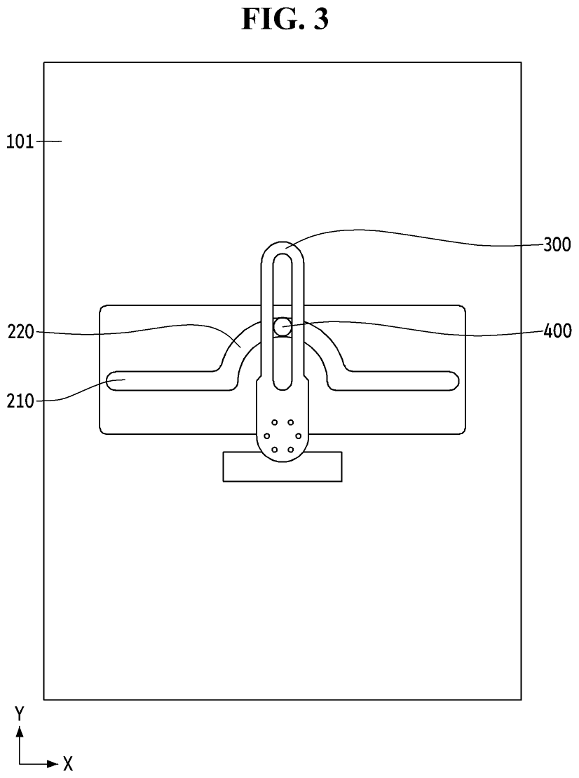

The first roller follower 410 may be positioned within a first hole H1 of the cam guide 300. The first roller follower 410 may be connected to the cam guide 300. The first hole H1 of the cam guide 300 may be an elongated, linearly extending opening (e.g., illustrated in FIG. 3) that is sized to receive the first roller follower 410. The first roller follower 410 may therefore translate within the first hole H1 and move relative to the cam guide 300 while inadvertent removal of the first roller follower 410 from the first hole H1 may be avoided. As illustrated in FIG. 3, when viewed from a plan view, the first hole H1 may be vertically aligned with a second hole H2 of the rail 200.

The second roller follower 420 may be positioned within a second hole H2 of the rail 200. The second roller follower 420 may be connected to the rail 200. The second hole H2 may form the straight section 210 and the curved section 220. The second roller follower 420 may therefore translate within the second hole H2 and move relative to the rail 200 while inadvertent removal of the second roller follower 420 from the second hole H2 may be avoided. Due to the vertical alignment of the first hole H1 and the second hole H2, the shaft 500 may extend vertically and may be received within both the first hole H1 and the second hole H2.

As the driving unit 100 operates, the first and second roller followers 410 and 420 may move along the rail 200. As the driving unit 100 operates, the first and second roller followers 410 and 420 may move continuously along the curved section 220 and the straight section 210. In this case, the first and second roller followers 410 and 420 may move in unison. For example, as the driving unit 100 operates, the driving unit 100 may cause the cam guide 300 to move, which may cause the first roller follower 410 to move relative to the cam guide 300 within the first hole H1. Movement of the first roller follower 410 may cause the shaft 500 to move as well. The shaft 500 movement may likewise cause the second roller follower 420 to move relative to the rail 200 within the second hole H2 (e.g., along the curved section 220 and the straight section 210). Accordingly, by moving in unison, the first roller follower 410 and the second roller follower 420 may move together at the same time and in the same direction, while being located at different vertical locations along the shaft 500.

The connection unit 110 may connect the cam guide 300 and the driving unit 100. For example, the connection unit 110 may extend in the first vertical direction +Z and/or the second vertical direction −Z and in the second horizontal direction Y. Accordingly, the first roller follower 410 may be connected to the driving unit 100 through the cam guide 300 and the connection unit 110. For example, power may be transmitted from the driving unit 100 to the cam guide 300 through the connection unit 110. As the driving unit 100 operates, the first roller follower 410 may move within the cam guide 300, connected to the driving unit 100 through the connection unit 110, and may be driven along with the cam guide 300. The connection unit 110 may comprise one or more mechanical or electrical components to facilitate a transfer of energy from the driving unit 100 to the cam guide 300. For example, the connection unit 110 may comprise gears, shafts, bearings, couplings, etc. such that the driving unit 100 may cause the cam guide 300 to move via the connection unit 110.

The shaft 500 may penetrate both the cam guide 300 and the rail 200 and may extend in the first vertical direction +Z and/or the second vertical direction −Z. The cam guide 300 and the rail 200 may each be connected to the shaft 500.

Specifically, the first roller follower 410 may include a first inner hole IH1, and the second roller follower 420 may include a second inner hole IH2. The shaft 500 may be positioned within the first and second inner holes IH1 and IH2 and may be connected to the first and second roller followers 410 and 420. For example, the second roller follower 420 may be connected to the cam guide 300 through the shaft 500 and the first roller follower 410. The shaft 500 may therefore transmit movement from the cam guide 300 to the second roller follower 420 and cause the second roller follower 420 to move relative to the rail 200.

The support unit 120 may be provided on the rail 200 in the first vertical direction +Z to support the driving unit 100. The rail 200 may be supported by a rail support plate 101 attached to the ceiling. The support unit 120 may be attached to the rail support plate 101.

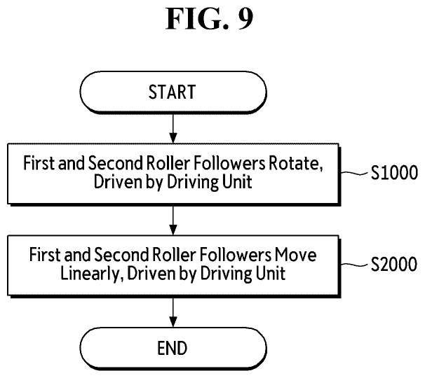

FIGS. 3 through 8 are plan views illustrating the operation of the transporting apparatus according to some embodiments. FIG. 9 is a flowchart illustrating the operation of the transporting apparatus according to some embodiments.

Specifically, FIGS. 3, 5, and 7 are plan views of the transporting apparatus according to some embodiments, as viewed from below. FIGS. 4, 6, and 8 are plan views of the transporting apparatus according to some embodiments, as viewed from above.

Referring to FIGS. 3 and 4, the driving unit 100 in FIG. 2 may be aligned at a first position. For example, the first position may correspond to a central position along the first horizontal direction X. Accordingly, the transported pod 600 may also be aligned at the first position.

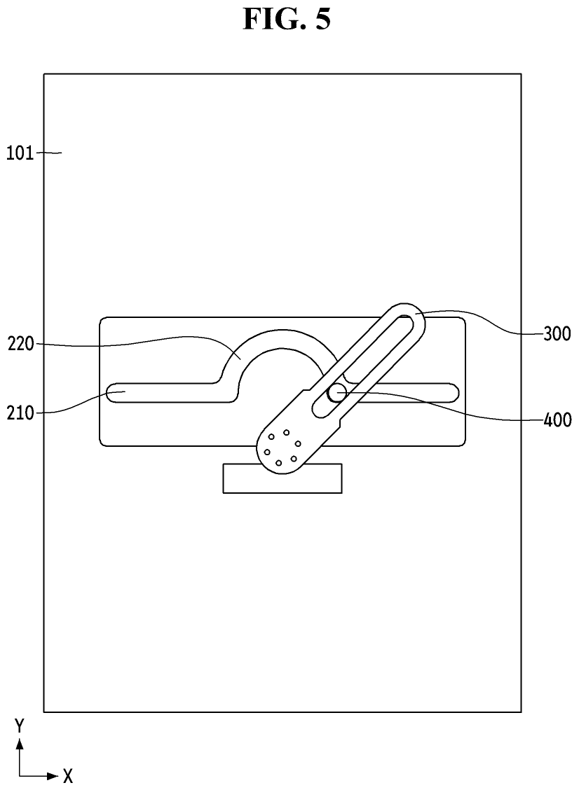

Referring to FIGS. 5, 6, and 9, the driving unit 100 may drive the roller follower 400 to rotate (S1000). For example, the driving unit 100 may output movement that may be transmitted through the connection unit 110 to the first roller follower 410 and the second roller follower 420.

Referring to FIG. 5, the driving unit 100 may operate to move the transported pod 600 in a first direction. For example, the first direction may be 90 degrees clockwise, but is not limited thereto. Although not specifically illustrated, the driving unit 100 may also operate to move counterclockwise by 90 degrees. For example, the driving unit 100 may cause the cam guide 300 to rotate in the clockwise direction (e.g., with the cam guide 300 in a first position in FIG. 3, and in a rotated second position in FIG. 5). This movement of the cam guide 300 may cause the first roller follower 410 to move relative to the cam guide 300, and may cause the second roller follower 420 to move relative to the rail 200 (e.g., within the curved section 220 to the intersection between the curved section 220 and the straight section 210).

Powered by the driving unit 100, the roller follower 400 may rotate along the curved section 220 in the first direction.

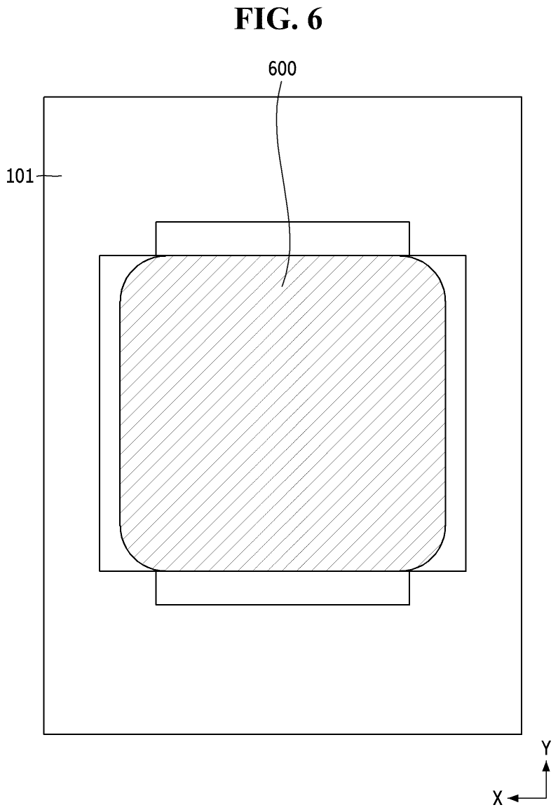

Referring to FIG. 6, as the roller follower 400 rotates in the first direction, the transported pod 600 may also rotate in the first direction.

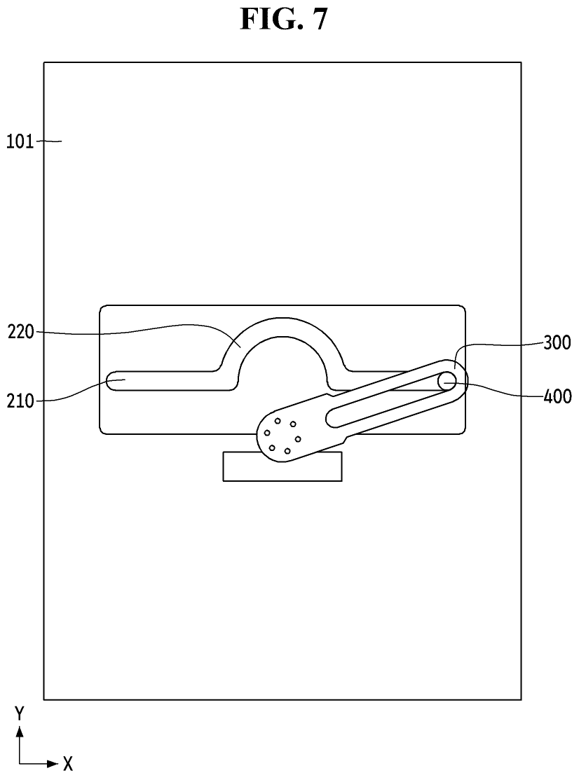

Referring to FIGS. 7, 8, and 9, the driving unit 100 may drive the roller follower 400 to move linearly (S2000). The linear movement may be performed continuously following the rotational movement. For example, the driving unit 100 may cause the cam guide 300 to continue to rotate in the clockwise direction (e.g., with the cam guide 300 in a second position in FIG. 5, and in a third position in FIG. 7). This movement of the cam guide 300 may cause the first roller follower 410 to move relative to the cam guide 300, and may cause the second roller follower 420 to move relative to the rail 200 (e.g., along the straight section 210). Accordingly, as the cam guide 300 continues to rotate, the first roller follower 410 may within the first hole H2 of the cam guide 300 from a central location of the cam guide 300 to an end of the cam guide 300.

Referring to FIG. 7, the driving unit 100 may operate to move the transported pod 600 in a second direction. For example, the second direction may correspond to the first horizontal direction X, but is not limited thereto. Although not specifically illustrated, if the driving unit 100 operates counterclockwise by 90 degrees, the roller follower 400 may move linearly in the direction opposite to the first horizontal direction X.

Powered by the driving unit 100, the roller follower 400 may move linearly along the straight section 210 in the second direction.

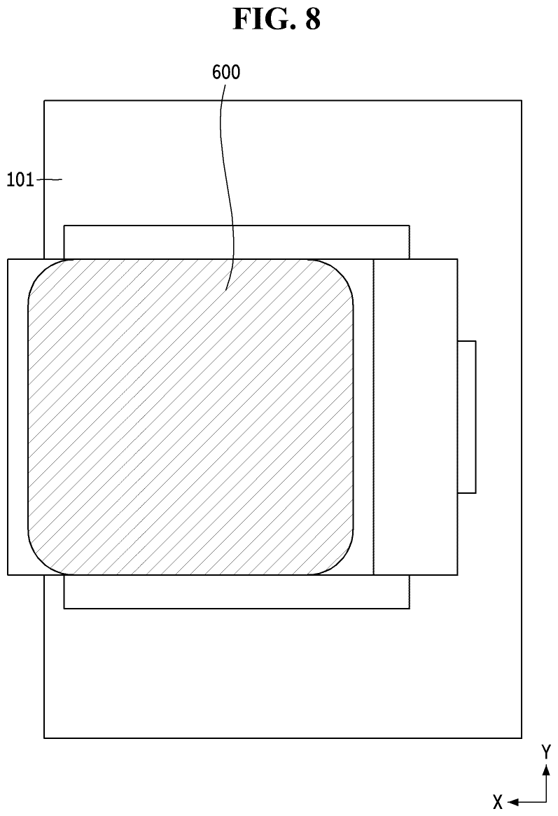

Referring to FIG. 8, as the roller follower 400 moves linearly in the second direction, the transported pod 600 may also move linearly in the second direction. For example, the transported pod 600 may be supported by the transporting apparatus, such that as the transporting apparatus moves (e.g., in the first direction, the second direction, etc.), the transported pod 600 may also move in the same direction. In this way, the transported pod 600 may move in the same direction that the shaft 500 moves when the shaft 500 moves within the straight section 210 and the curved section 220.

The roller follower 400 may move continuously along the curved section 220 and the straight section 210, driven by the driving unit 100. For example, using a single driving unit 100, the transported pod 600 may move continuously in different directions. Specifically, the first and second roller followers (“410” and “420” in FIG. 2) may move in unison along the curved section 220 in the first direction and along the straight section 210 in the second direction. As the roller followers 410, 420 move along the curved section 220 in the first direction and along the straight section 210 in the second direction, the pod 600 may also move in the same direction.

The first roller follower 410 may be driven by the driving unit 100, and the second roller follower 420, connected to the first roller follower 410 via the shaft 500, may also be driven. As a result, the first and second roller followers 410 and 420 may move in the first and second directions. For example, the movements in the first and second directions may be achieved as a continuous operation using a single driving unit 100. For example, the single driving unit 100 may cause the pod 600 to move in a plurality of horizontal directions (e.g., the x-direction, the y-direction), such that movement of the pod 600 is not limited to a single, linear, horizontal direction.

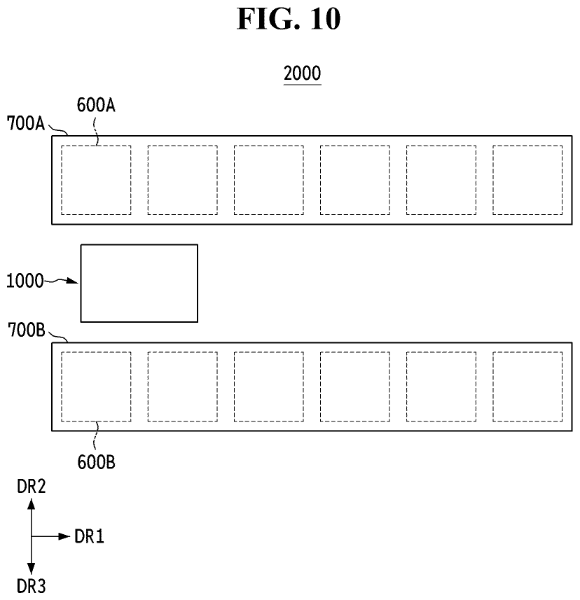

FIG. 10 illustrates a transporting system including the transporting apparatus according to some embodiments. For convenience of explanation, overlapping content with what has been described with reference to FIGS. 1 through 9 may be omitted.

Referring to FIG. 10, a transporting system 2000 according to some embodiments may include first and second locations 700A and 700B and a transporting robot including the transporting apparatus 1000. In some embodiments, the first and second locations 700A, 700B may comprise shelves, for example, a first shelf (e.g., location 700A) and a second shelf (e.g., location 700B). However, the first and second locations 700A, 700B are not limited to shelves, and are merely intended to represent two different areas at which pods 600A and 600B may be positioned.

The first and second locations 700A and 700B may represent locations where transported pods 600A and 600B are stored. The transporting apparatus 1000 may move the transported pods 600A and 600B between the first and second locations 700A and 700B.

For example, the transported pods 600A and 600B may move linearly in a direction parallel to a first direction DR1, move vertically in a fourth direction (not illustrated), or rotate in a second direction DR2 and a third direction DR3, opposite to the second direction DR2. The fourth direction may represent the height direction perpendicular to the first, second, and third directions DR1, DR2, and DR3. As such, FIG. 10 may represent a top-down plan view of the transporting system 2000.

When the transporting robot moves linearly in a direction parallel to the first direction DR1 or vertically in the fourth direction to locate a specific location between the locations 700A and 700B, the transporting apparatus 1000 may rotate the transported pods 600A and 600B in the second and third directions DR2 and DR3. The transporting robot may be a self-contained autonomous robot that may comprise one or more wheels to move the transporting robot in a direction, for example, the first direction DR1. Alternatively, the transporting robot may rest upon, or may be supported by, one or more rails that may extend in a direction, for example, the first direction DR1. As such, the transporting robot may move the transporting apparatus 1000 in the first direction DR1. In some embodiments, the transporting robot may comprise a lifting mechanism that may vertically move a portion of the transporting robot in a vertical up and down direction. As such, the transporting robot may move the transporting apparatus 1000 in a vertical direction that is perpendicular to the directions DR1, DR2, and DR3.

For example, the transporting robot may move by a first length in a direction parallel to the first direction DR1 and/or by a second length in the fourth direction to correspond to the specific location, and then rotate the transported pods 600A and 600B in the second and third directions DR2 and DR3 into the specific location.

The same description provided with reference to FIGS. 1 through 9 may also be applicable to the transporting apparatus 1000.

Referring again to FIGS. 1, 2, and 10, the transporting apparatus 1000 may have a first length D1 in the first horizontal direction X, a second length D2 in the second horizontal direction Y, and a third length D3 in the first vertical direction +Z. For example, the third length D3 may be smaller than the first and second lengths D1 and D2, but is not limited thereto.

For example, the first length D1 of the transporting apparatus 1000 in the first horizontal direction X may be, but is not limited to, 340 mm, the second length D2 of the transporting apparatus 1000 in the second horizontal direction Y may be, but is not limited to, 290 mm, and the third length D3 of the transporting apparatus 1000 in the first vertical direction +Z may be, but is not limited to, 126 mm. In some embodiments, the first length D1 may be within a range from 200 mm to 500 mm, or 300 mm to 400 mm. In some embodiments, the second length D2 may be within a range from 200 mm to 400 mm, or 250 mm to 350 mm. In some embodiments, the third length D3 may be within a range from 50 mm to 200 mm, or 100 mm to 150 mm.

Transported objects such as front opening unified pods (FOUPs) for housing wafers in semiconductor device manufacturing processes may be stored in the first and second locations 700A and 700B. To smoothly move the transported pods from the first and second locations 700A and 700B, a transporting apparatus with a reduced spatial footprint may be provided.

According to some embodiments, a transporting apparatus capable of continuously performing rotational and linear movements of transported pods using a single driving unit can be provided. As a result, a transporting apparatus with enhanced usability can be provided by reducing its spatial footprint while minimizing the number of driving units. For example, in a semiconductor manufacturing facility, limited space may exist for transporting and moving semiconductor-related objects. In particular, ceiling height is one consideration when transporting these semiconductor-related objects. The transporting apparatus 1000 provided herein may comprise a single driving unit 110, which may occupy less space than a plurality of driving units. For example, the transporting apparatus 1000 may have a reduced vertical height. The single driving unit 110 of the transporting apparatus 1000 may still drive movement in a plurality of directions (e.g., multi-axis driving) while occupying less space.

While embodiments of the present disclosure have been described with reference to the accompanying drawings, the present disclosure is not limited to the disclosed embodiments and may be embodied in various forms. Those skilled in the art will understand that modifications can be made without departing from the spirit or essential characteristics of the present disclosure. Thus, the disclosed embodiments are illustrative, not restrictive, in all aspects.

What is claimed is:

1. A transporting apparatus for transporting a pod that is configured to house one or more semiconductor wafers, the transporting apparatus comprising:
a rail including a straight section and a curved section that form a transport path for the pod;
a driving unit configured to provide power to move the pod along the rail;
a cam guide positioned between the rail and the driving unit and connected to the driving unit;
a first roller follower positioned within a hole of the cam guide; and
a second roller follower positioned within a hole of the rail,
wherein the driving unit is configured to move the cam guide, the first roller follower is configured to move within the hole of the cam guide, and the second roller follower is configured to move relative to the rail.

2. The transporting apparatus of claim 1, wherein as the cam guide moves, the first and second roller followers move along the straight section and the curved section.

3. The transporting apparatus of claim 1, wherein the first and second roller followers are attached to a shaft that is positioned within the hole of the cam guide and the hole of the rail such that the first and second roller followers move in unison.

4. The transporting apparatus of claim 1, wherein
the hole in the cam guide is elongated such that the first roller follower is configured to translate along the hole.

5. The transporting apparatus of claim 1, further comprising:
a connection unit connecting the cam guide and the driving unit.

6. The transporting apparatus of claim 5, wherein the driving unit is configured to move the connection unit, and the connection unit is configured to move the first roller follower and the cam guide.

7. The transporting apparatus of claim 1, further comprising:
a shaft extending vertically through the hole in the cam guide and the hole in the rail,
wherein the first and second roller followers are each connected to different locations of the shaft such that the first and second roller followers are spaced apart from one another.

8. The transporting apparatus of claim 7, wherein the second roller follower is connected to the cam guide via the shaft and the first roller follower.

9. The transporting apparatus of claim 1, further comprising:
a support unit configured to attach the driving unit to the rail.

10. A transporting apparatus for transporting a pod that is configured to house one or more semiconductor wafers, the transporting apparatus comprising:
a rail including a first rail section, along which the pod is movable in a first direction, and a second rail section, along which the pod is movable in a second direction different from the first direction;
a driving unit configured to provide power to move the pod along the rail;
a cam guide positioned between the rail and the driving unit in a vertical direction and connected to the driving unit;
a first roller follower connected to the cam guide;
a second roller follower connected to the rail; and
a shaft extending vertically through the cam guide and the rail, the shaft connecting the first roller follower and the second roller follower,
wherein the driving unit is configured to move the cam guide, the first roller follower is configured to move relative to the cam guide, the second roller follower is configured to move relative to the rail, and the first and second roller followers move in the first and second directions.

11. The transporting apparatus of claim 10, wherein the second roller follower is configured to rotate as the second roller follower moves along the first rail section in the first direction.

12. The transporting apparatus of claim 11, wherein as the second roller follower rotates while moving in the first direction, the pod is configured to rotate while moving in the first direction.

13. The transporting apparatus of claim 10, wherein the second roller follower is configured to move linearly along the second rail section in the second direction.

14. The transporting apparatus of claim 13, wherein as the second roller follower moves linearly in the second direction, the pod is configured to move linearly in the second direction.

15. A transporting system comprising:
first and second locations where pods that are configured to house one or more semiconductor wafers are stored; and
a transporting robot movable in a horizontal direction and a vertical direction, wherein
the transporting robot includes a transporting apparatus configured to move a pod between the first and second locations,
the transporting apparatus includes:
a rail including a curved section and a straight section connected to the curved section,
a driving unit configured to provide power to move the pod along the rail,
a cam guide positioned between the rail and the driving unit in the vertical direction and connected to the driving unit,
a first roller follower positioned within and connected to the cam guide;
a second roller follower positioned within and connected to the rail, and
a shaft extending vertically through the cam guide and the rail, wherein the first and second roller followers are attached to the shaft, and
the driving unit is configured to move the cam guide, the first roller follower is configured to move relative to the cam guide, and the second roller follower is configured to move relative to the rail, wherein the first and second roller followers move along the curved section and the straight section.

16. The transporting system of claim 15, wherein the first and second roller followers move in unison along the curved section and the straight section.

17. The transporting system of claim 15, wherein
the first roller follower includes a first inner hole,
the second roller follower includes a second inner hole, and
the shaft is positioned within the first and second inner holes to connect the first and second roller followers.

18. The transporting system of claim 15, wherein
the transporting apparatus further includes a connection unit connecting the cam guide and the driving unit, and
the first roller follower is connected to the driving unit via the connection unit and the cam guide.

19. The transporting system of claim 15, wherein the second roller follower is connected to the cam guide via the shaft.

20. The transporting system of claim 15, wherein the transporting robot moves by a first length in the horizontal direction and a second length in the vertical direction to correspond to a specific locations between the first and second locations, and the transporting apparatus is configured to rotate the pod when moving the pod to one of the first location or the second location, and wherein the transporting apparatus is located between first location and the second location such that the first location is on an opposite side of the transporting apparatus from the second location.
